(19) United States
(12) Patent Application Publication
(10) Pub. No.: US 2023/0049118 A1
(43) Pub. Date: Feb. 16, 2023

(54) SUBSTRATE PROCESSING DEVICE AND SUBSTRATE PROCESSING METHOD

(71) Applicant: JUSUNG ENGINEERING CO., LTD., Gwangju-si, Gyeonggi-do (KR)

(72) Inventors: InSeo YOO, Gwangju-si, Gyeonggi-do (KR); ChulJoo HWANG, Gwangju-si, Gyeonggi-do (KR)

(21) Appl. No.: 17/792,706

(22) PCT Filed: Jan. 29, 2021
(86) PCT No.: PCT/KR2021/001205

§ 371 Date: Jul. 13, 2022

(30) Foreign Application Priority Data
Jan. 31, 2020 (KR) 10-2020-0012184

(51) Int. Cl. H01J 37/32; C23C 16/458; C23C 16/44; C23C 16/455; C23C 16/505

(52) U.S. Cl. CPC H01J 37/3244; H01J 37/32715; C23C 16/4588; C23C 16/4408; C23C 16/45536; C23C 16/45548; C23C 16/45574; C23C 16/505; H01J 2237/201; H01J 2237/20214; H01J 2237/332; H01J 37/32357

(57) ABSTRACT

The present inventive concept relates to a substrate processing device and a substrate processing method. The substrate processing device comprises: a chamber; a substrate support part rotatably installed in a process space inside the chamber so as to allow at least one substrate to be seated thereon; a first gas spray unit for spraying, to a first region of the process space, a source gas and a first purge gas for purging the source gas; a source gas supply source for supplying the source gas to the first gas spray unit; a first purge gas supply source for supplying the first purge gas to the first gas spray unit; a second gas spray unit spatially separated from the first region and configured to spray, to a second region of the process space, a reactant gas reacting with the source gas and a second purge gas for purging the reactant gas; a reactant gas supply source for supplying the reactant gas to the second gas spray unit; and a second purge gas supply source for supplying the second purge gas to the second gas spray unit.

### TECHNICAL FIELD

The present inventive concept relates to an apparatus for processing a substrate, which performs a processing process such as a deposition process and an etching process on a substrate.

### BACKGROUND ART

Generally, a thin-film layer, a thin-film circuit pattern, or an optical pattern should be formed on a substrate for manufacturing a solar cell, a semiconductor device, a flat panel display device, etc. To this end, a processing process is performed, and examples of the processing process include a deposition process of depositing a thin film including a specific material on a substrate, a photo process of selectively exposing a portion of a thin film by using a photosensitive material, an etching process of removing the selectively exposed portion of the thin film to form a pattern, etc.

A process of forming a thin film on a substrate or removing the thin film is performed by supplying the substrate with a gas for forming a specific material, a gas for selectively removing the specific material, or a material corresponding thereto. Particularly, the process of forming the thin film may be performed by supplying a reactant gas and a source gas for forming a specific material, and in this case, the source gas and the reactant gas may be simultaneously supplied to the substrate or may be sequentially supplied to the substrate with a time difference therebetween.

As a semiconductor device manufacturing process advances to a fine process, various methods for forming a uniform thin film on a fine pattern formed on a surface of a substrate or forming a pattern are being applied, and one of the various methods is an atomic layer deposition (ALD) process. The ALD process is a process which does not simultaneously supply a source gas and a reactant gas but supplies the source gas and the reactant gas with a time difference therebetween to induce only a reaction performed on the surface of the substrate, forming a thin film on the substrate through a reaction between the source gas and the reactant gas. The source gas may be adsorbed onto the surface of the substrate by supplying the source gas to the substrate first, and then, the other source gas may be removed by using a purge gas. Subsequently, by supplying the reactant gas to the substrate, the reactant gas may react with the source gas adsorbed onto the surface of the substrate, and then, the other reactant gas may be purged by using the purge gas. In a step of supplying the reactant gas, an atomic layer or a single-layer thin film is formed on the surface of the substrate on the basis of the reaction between the source gas and the reactant gas. Such a procedure may be repeated up to a desired thickness, and thus, a thin film having a certain thickness may be formed on the surface of the substrate.

However, in the ALD process, since the reaction between the source gas and the reactant gas is performed on only the surface of the substrate, there is a disadvantage where a speed at which a thin film is deposited is lower than a general chemical vapor deposition (CVD) process and the like.

Also, a process of quickly repeating a step of supplying the source gas to the same process space, purging the supplied source gas, supplying the reactant gas, and purging the reactant gas has a drawback where a time is long expended. In a case where a process is quickly repeated, the supplied source gas or reactant gas is not completely discharged (purged) from the process space to the outside of a chamber, and due to this, an atomic layer thin film is not formed, causing a drawback where two gases meet each other to form a CVD thin film.

In a process of quickly supplying a source gas or a reactant gas and an ALD process based on the source gas or the reactant gas, a structure where the two gases are not mixed in a process and a pure ALD film are needed.

### DISCLOSURE

### Technical Problem

The present inventive concept is devised to solve the above-described problem and has a technical problem for providing a process chamber in which a source gas and a reactant gas are not mixed in a space.

Moreover, the present inventive concept has a technical problem of providing an apparatus and a method, which adsorb a source gas and generate radio frequency (RF) plasma from a purge gas in the same space to enhance the quality of an adsorption film, in forming a thin film through an atomic layer deposition (ALD) process.

Moreover, the present inventive concept has a technical problem of providing an apparatus which forms a film (a pure ALD layer) using a pure ALD process on a substrate to densify a certain thin film or improve film quality.

Moreover, the present inventive concept has a technical problem of providing an apparatus which purges a reactant gas remaining on a substrate quickly moving from a reactant gas space to a source gas space and simultaneously supplies plasma to a portion of a purge gas supply unit supplying a purge gas for quickly purging impurities of a generated thin film, in a purge gas space for separating the source gas space and the reactant gas space.

### Technical Solution

A substrate processing apparatus according to the present inventive concept for accomplishing the above-described objects may include: a chamber; a substrate supporting unit where one or more substrates are mounted in a process space of the chamber, the substrate supporting unit being rotatably installed; a first gas injection unit for injecting a source gas and a first purge gas into a first region of the process space, the first purge gas is for purging the source gas; a source gas supply source for supplying the source gas to the first gas injection unit; a first purge gas supply source for supplying the first purge gas to the first gas injection unit; a second gas injection unit for injecting a reactant gas and a second purge gas into a second region of the process space spatially apart from the first region, the reactant gas is for reacting with the source gas and the second purge gas is for purging the reactant gas; a reactant gas supply source for supplying the reactant gas to the second gas injection unit; and a second purge gas supply source for supplying the second purge gas to the second gas injection unit.

In the substrate processing apparatus according to the present inventive concept, the first gas injection unit may include: a plurality of source gas injection holes injecting the source gas; and a plurality of first purge gas injection holes injecting the first purge gas.

In the substrate processing apparatus according to the present inventive concept, the second gas injection unit may include: a plurality of reactant gas injection holes injecting the reactant gas; and a plurality of second purge gas injection holes injecting the second purge gas.

In the substrate processing apparatus according to the present inventive concept, the second gas injection unit may inject one or more of the reactant gas and the second purge gas as plasma.

In the substrate processing apparatus according to the present inventive concept, the second gas injection unit may include a second electrode unit for converting the reactant gas or the second purge gas into plasma.

In the substrate processing apparatus according to the present inventive concept, the first gas injection unit may inject the first purge gas as plasma.

In the substrate processing apparatus according to the present inventive concept, the first gas injection unit may include a first electrode unit for converting the first purge gas into plasma.

In the substrate processing apparatus according to the present inventive concept, the second gas injection unit may include a plurality of reactant gas injection holes injecting the reactant gas and a plurality of second purge gas injection holes injecting the second purge gas. The source gas, the first purge gas, the reactant gas, and the second purge gas may be injected in order. The second gas injection unit may inject the first purge gas as plasma. The second gas injection unit may inject one or more of the reactant gas and the second purge gas as plasma.

In the substrate processing apparatus according to the present inventive concept, the second gas injection unit may further include a treatment gas supply source connected to one of the reactant gas injection hole and the second purge gas injection hole.

In the substrate processing apparatus according to the present inventive concept, the second gas injection unit may inject a second purge gas, and then, may inject a treatment gas as plasma.

In the substrate processing apparatus according to the present inventive concept, the second gas injection unit may include a plurality of reactant gas injection holes injecting the reactant gas and a plurality of second purge gas injection holes injecting the second purge gas, and the second gas injection unit comprises a treatment gas supply source connected to one of the reactant gas injection hole and the second purge gas injection hole. The source gas, the first purge gas, the reactant gas, the second purge gas, and the treatment gas may be injected in order. The second gas injection unit may inject the treatment gas as plasma. The second gas injection unit may inject one or more of the reactant gas and the second purge gas as plasma.

In the substrate processing apparatus according to the present inventive concept, each of the first electrode unit and the second electrode unit may be configured with a first electrode and a second electrode having an electric potential difference therebetween. Plasma may be generated by injecting one of the first purge gas, the reactant gas, and the second purge gas into a region between the first electrode and the second electrode.

The substrate processing apparatus according to the present inventive concept may further include: a third gas injection unit injecting a third purge gas into a third region between the first region and the second region; and a third purge gas supply source injecting the third purge gas into the third gas injection unit.

In the substrate processing apparatus according to the present inventive concept, the third purge gas may be injected in a plasma state.

In the substrate processing apparatus according to the present inventive concept, the third purge gas unit may include a third electrode unit for converting the third purge gas into plasma.

In the substrate processing apparatus according to the present inventive concept, the third electrode unit may be configured with a first electrode and a second electrode having an electric potential difference therebetween. Plasma may be generated by injecting the third purge gas into a region between the first electrode and the second electrode.

In the substrate processing apparatus according to the present inventive concept, one of the first purge gas, the reactant gas, and the second purge gas may be connected to a remote plasma generating device.

A substrate processing method according to the present inventive concept may include: a step of mounting each of a first substrate and a second substrate on a substrate supporting unit disposed in a chamber so that the first substrate is disposed in a first region of a process space of the chamber and a second substrate is disposed in a second region of the process space spatially apart from the first region; a source adsorbing step of injecting a source gas onto the first substrate in the first region to adsorb a first source gas onto the first substrate; a first rotation step of rotating the substrate supporting unit so that the first substrate with the first source gas adsorbed thereon is disposed in the second region; a thin film forming step of injecting a reactant gas onto the first substrate in the second region to form a thin film through a reaction between the reactant gas and a first source gas adsorbed onto the first substrate; and a second rotation step of rotating the substrate supporting unit so that the first substrate with the thin film formed thereon is disposed in the first region. A thin film having a predetermined thickness may be formed by repeating the source adsorbing step, the first rotation step, the thin film forming step, and the second rotation step a plurality of times.

The substrate processing method according to the present inventive concept may include a source purging step of injecting a first purge gas, which is for purging the source gas, onto the first substrate after the source adsorbing step.

The substrate processing method according to the present inventive concept may include a reactant gas purging step of injecting a second purge gas, which is for purging the reactant gas, onto the first substrate after the thin film forming step.

In the substrate processing method according to the present inventive concept, one or more of the reactant gas and the second purge gas may be generated as plasma and injected.

In the substrate processing method according to the present inventive concept, the first purge gas may be generated as plasma and injected.

The substrate processing method according to the present inventive concept may include a reactant gas purging step of injecting a second purge gas, which is for purging the reactant gas, onto the first substrate after the thin film forming step. The first purge gas may be generated as plasma and injected. One or more of the reactant gas and the second purge gas may be generated as plasma and injected.

The substrate processing method according to the present inventive concept may include a treatment gas injecting step of injecting a treatment gas for performing treatment on the thin film after the reactant gas purging step.

In the substrate processing method according to the present inventive concept, the treatment gas may be generated as plasma and injected.

The substrate processing method according to the present inventive concept may include: a reactant gas purging step of injecting a second purge gas, which is for purging the reactant gas, onto the first substrate after the thin film forming step; and a treatment gas injecting step of injecting a treatment gas for performing treatment on the thin film after the reactant gas purging step. The treatment gas may be generated as plasma and injected. One or more of the first purge gas, the reactant gas, and the second purge gas may be generated as plasma and injected. In the substrate processing method according to the present inventive concept, a first electrode unit disposed in the first region and a second electrode unit disposed in the second region may be provided. Each of the first electrode unit and the second electrode unit may be configured with a first electrode and a second electrode having an electric potential difference therebetween. Plasma may be generated by injecting one of the first purge gas, the reactant gas, the second purge gas, and the treatment gas into a region between the first electrode and the second electrode.

In the substrate processing method according to the present inventive concept, in the first rotation step or the second rotation step, a third purge gas may be injected for dividing the first region and the second region.

In the substrate processing method according to the present inventive concept, in the first rotation step or the second rotation step, a third purge gas is injected for additionally purging the first source gas adsorbed onto the first substrate or additionally purging the reactant gas formed on the first substrate.

In the substrate processing method according to the present inventive concept, the third purge gas may be generated as plasma and injected.

In the substrate processing method according to the present inventive concept, in the first rotation step or the second rotation step, a third purge gas is injected for dividing the first region and the second region.

In the substrate processing method according to the present inventive concept, the third purge gas may be generated as plasma and injected.

In the substrate processing method according to the present inventive concept, the reactant gas may be injected onto the second substrate in the second region in the source adsorbing step. The substrate processing method according to the present inventive concept may further include injecting the source gas onto the second substrate in the first region in the thin film forming step. Injecting the source gas onto the first substrate in the first region and injecting the reactant gas onto the second substrate in the second region may be simultaneously performed.

In the substrate processing method according to the present inventive concept, the reactant gas may be injected onto the second substrate in the second region in the source adsorbing step. The substrate processing method according to the present inventive concept may further include injecting the source gas onto the second substrate in the first region in the thin film forming step. Injecting the reactant gas onto the first substrate in the second region and injecting the source gas onto the second substrate in the first region may be simultaneously performed.

### Advantageous Effect

According to a solution means for the problem, a substrate processing apparatus according to the present inventive concept may form a pure ALD thin film through a purge gas injection space for completely dividing a process space of a chamber into a source gas injection space and a reactant gas injection space.

Moreover, the substrate processing apparatus according to the present inventive concept may generate plasma in the source gas injection space, the reactant gas injection space, and the purge gas injection space to remove a film adsorbed onto a substrate and the internal impurities of an ALD thin film, thereby forming a high-quality ALD thin film and a pure ALD thin film.

### DESCRIPTION OF DRAWINGS

FIG. 1 is a diagram schematically illustrating a shape of a substrate processing apparatus according to an embodiment of the present inventive concept.

FIG. 2 is a diagram for describing a lid of a chamber in a substrate processing apparatus according to an embodiment of the present inventive concept.

FIG. 3 is a schematic diagram taken along line A′-A′ of FIG. 1 for describing an upper lid of a chamber in a substrate processing apparatus according to an embodiment of the present inventive concept.

### MODE FOR INVENTIVE CONCEPT

The terms described in the specification should be understood as follows.

As used herein, the singular forms “a”, “an” and “the” are intended to include the plural forms as well, unless the context clearly indicates otherwise. The terms “first” and “second” are for differentiating one element from the other element, and these elements should not be limited by these terms.

It will be further understood that the terms “comprises”, “comprising,”, “has”, “having”, “includes” and/or “including”, when used herein, specify the presence of stated features, integers, steps, operations, elements, and/or components, but do not preclude the presence or addition of one or more other features, integers, steps, operations, elements, components, and/or groups thereof.

The term “at least one” should be understood as including any and all combinations of one or more of the associated listed items. For example, the meaning of “at least one of a first item, a second item, and a third item” denotes the combination of all items proposed from two or more of the first item, the second item, and the third item as well as the first item, the second item, or the third item.

The term “on” should be construed as including a case where one element is formed at a top of another element and moreover a case where a third element is disposed therebetween.

Hereinafter, preferable embodiments according to the present inventive concept will be described in detail with reference to the drawings.

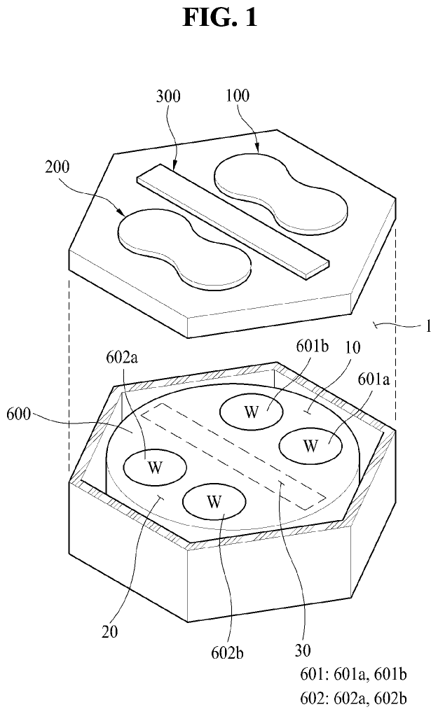

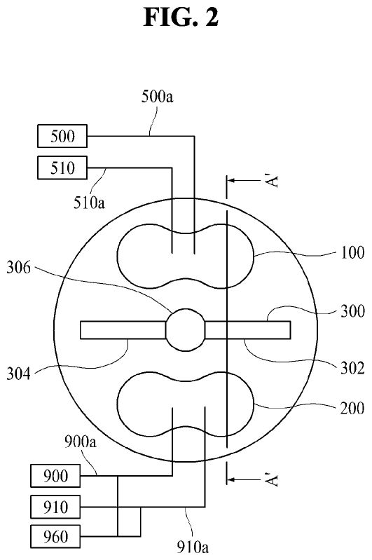

FIG. 1 is a diagram schematically illustrating a substrate processing apparatus according to an embodiment of the present inventive concept. FIG. 2 is a plan view as an upper lid is seen from above, in a chamber where a top surface thereof is cut.

Referring to FIGS. 1 and 2, in the substrate processing apparatus according to the present inventive concept, a process space 1 may be provided in the chamber. The upper lid may be provided at an upper portion of the process space 1 of the chamber, and a substrate supporting unit 600 may be provided at a lower portion of the process space 1 of the chamber. One or more substrates (i.e., a plurality of substrates) may be rotatably installed on the substrate supporting unit 600 and may be arranged at a certain interval or to be paired on the substrate supporting unit 600.

A first substrate 601 may be disposed in a first region 10 on the substrate supporting unit 600, and the first substrate 601 may be a plurality of substrates. The first substrate 601 may be configured with a first wafer 601a and a second wafer 601b, but is not limited thereto and three or four wafers may be disposed in only the first region 10. A second substrate 602 may be disposed in a second region 20, and the second substrate 602 may be a plurality of substrates. The second substrate 602 may be configured with a third wafer 602a and a fourth wafer 602b , but is not limited thereto and three or four wafers may be disposed in only the second region 20.

The process space 1 of the chamber may be divided into the first region 10, the second region 20, and a third region 30.

A first gas injection unit 100 for injecting a source gas from a source gas supply source 500 into the first region 10 through a source gas line 500a may be disposed in the first region 10. The first gas injection unit 100 for injecting a first purge gas from a first purge gas supply source 510 into the first region 10 through a first purge gas line 510a may be disposed in the first region 10.

A reactant gas supply source 900 may supply a reactant gas, reacting with the source gas, to the second region 20 which is spatially apart from the first region 10 in the process space 1, the supplied reactant gas may be connected to a second gas injection unit 200 through a reactant gas line 900a and may be injected into the second region 20 by the second gas injection unit 200, and a second purge gas supplied through a second purge gas line 910a from a second purge gas supply source 910 may be connected to the second gas injection unit 200 and may be injected into the second region 20 by the second gas injection unit 200. Also, the second purge gas may be injected for purging a reactant gas, remaining in a space, from the second region 20. The first gas injection unit 100 and the second gas injection unit 200 may be coupled to an upper lid.

The third region 30 which divides the process space 1 of the chamber into the first region 10 and the second region 20 may be provided. The third region 30 may divide the process space 1 of the chamber into the first region 10 and the second region 20 with the purge gas so that the source gas which is in the first region 10 is not mixed with the reactant gas which is in the second region 20. A third gas injection unit 300 injecting a third purge gas may be disposed in the third region 30, and a third purge gas supply source (not shown) may be connected to the third gas injection unit 300 through a third purge gas line (not shown) and may inject the third purge gas into the third region 30. The third gas injection unit 300 may be coupled to the upper lid.

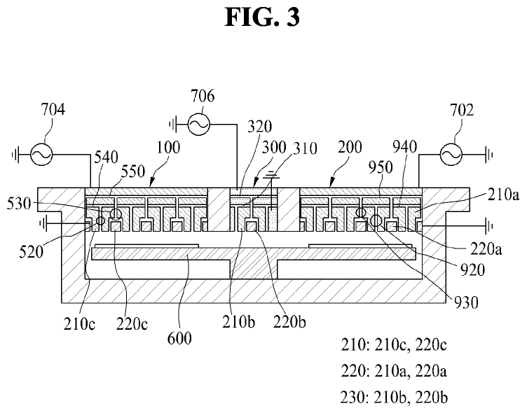

The drawing illustrating a chamber electrode structure in detail may be FIG. 3. The first gas injection unit 100 which injects the source gas and the first purge gas into the first region 10, the second gas injection unit 200 which injects the reactant gas and the second purge gas into the second region 20, and the third gas injection unit 300 which injects the third purge gas into the third region 30 may be provided.

The first gas injection unit 100 which injects the source gas and the first purge gas into the first region 10 may include a first electrode unit 210. The first electrode unit 210 may include a first electrode 210c and a second electrode 220c . The first electrode 210c and the second electrode 220c may have an electric potential difference, and the source gas or the first purge gas may pass through a region between the first electrode 210c and the second electrode 220c and thus may be plasmatic, and may be injected into the first region 10.

A first flow path 540 and a second flow path 550 may be installed in the first gas injection unit 100, and a structure of a gas flow path of the first flow path 540 and the second flow path 550 may be a flow path having a gun drill structure having a long-hole pipe shape. The first flow path 540 and the second flow path 550 may be formed to pass through an inner portion of the first electrode 210c , and the first flow path 540 may allow the source gas to be injected from a source gas injection hole 520 of an end of a protrusion portion (not shown) which protrudes in a direction toward a substrate. The source gas injection hole 520 formed at the end of the protrusion portion may be connected to the first flow path 540, and the source gas may be supplied to the first flow path 540 by the source gas supply source 500, connected to a plurality of source gas injection holes 520, and injected into the first region 10. The second flow path 550 may be connected to a plurality of first purge gas injection holes 530 which are provided in a space in an upward direction with respect to the second electrode 220c . The plurality of first purge gas injection holes 530 provided in a space on the second electrode 220c may be connected to the second flow path 550, and the first purge gas may be supplied from the first purge gas supply source 510 to the second flow path 550, connected to the plurality of first purge gas injection holes 530, and injected into the first region 10. In this case, the first purge gas may pass through a region between the first electrode 210c and the second electrode 220c having an electric potential difference and may be injected into the first region 10 in a plasma state. The first gas injection unit 100 may convert one or more of the source gas and the first purge gas into plasma and may inject the source gas or the first purge gas into the first region 10 in a plasma state. The first gas injection unit 100 may simultaneously inject a plasmatic source gas and a plasmatic first purge gas into the first region 10, or may inject the plasmatic source gas or the plasmatic first purge gas into the first region 10. Also, the first purge gas may be supplied to the first flow path 540, in order to clean the internal particles of the first flow path 540. On the other hand, the first purge gas may be supplied to the first flow path 540, and the source gas may be injected into the second flow path 550. Alternatively, the source gas or the first purge gas simultaneously supplied to the first flow path 540 and the second flow path 550 may be injected into the first region 10.

The second gas injection unit 200 which injects the reactant gas and the second purge gas may include the second electrode unit 220. The second electrode unit 220 may include a first electrode 210a and a second electrode 220a . The first electrode 210a and the second electrode 220a may have an electric potential difference, and the reactant gas or the second purge gas may pass through a region between the first electrode 210a and the second electrode 220a and thus may be injected into the second region 20 in a plasma state.

A third flow path 940 and a fourth flow path 950 may be installed in the second gas injection unit 200, and the third flow path 940 and the fourth flow path 950 may be a flow path having a gun drill structure having a long-hole pipe shape. The third flow path 940 and the fourth flow path 950 may pass through the first electrode 210a , and the third flow path 940 may allow the reactant gas to be injected from a reactant gas injection hole 920 of an end of a protrusion portion (not shown) which protrudes in a direction toward a substrate. The third flow path 940 may be connected to the reactant gas injection hole 920 of the end of the protrusion portion, and the reactant gas may be supplied to the third flow path 940 by the reactant gas supply source 900, connected to a plurality of reactant gas injection holes 920, and injected into the second region 20. In this case, the reactant gas may pass through a region between the first electrode 210a and the second electrode 220a having an electric potential difference and may be injected into the second region 20 in a plasma state. Also, the fourth flow path 950 may be connected to a plurality of second purge gas injection holes 930 provided in a space on the second electrode 220a . The plurality of second purge gas injection holes 930, which are provided in a space in an upward direction with respect to the second electrode 220a , may be connected to the fourth flow path 950, and the second purge gas may be supplied from the second purge gas supply source 910 to the fourth flow path 950, connected to the plurality of second purge gas injection holes 930, and injected into the second region 20. In this case, the second purge gas may pass through a region between the first electrode 210a and the second electrode 220a having an electric potential difference and may be injected into the second region 20 in a plasma state. The second gas injection unit 200 may convert one or more of the reactant gas and the second purge gas into plasma and may inject the reactant gas or the second purge gas into the second region 20 in a plasma state. The second gas injection unit 200 may simultaneously inject a plasmatic reactant gas and a plasmatic second purge gas into the second region 20, or may inject the plasmatic reactant gas or the plasmatic second purge gas into the second region 20. The second purge gas may be supplied to the third flow path 940, in order to clean the internal particles of the third flow path 940. On the other hand, the reactant gas may be supplied to the fourth flow path 950, and the second purge gas may be injected into the third flow path 940. Alternatively, the reactant gas or the second purge gas simultaneously supplied to the third flow path 940 and the fourth flow path 950 may be injected into the second region 20.

The second gas injection unit 200 may include a plurality of reactant gas injection holes 920 which inject the reactant gas and a plurality of second purge gas injection holes 930 which inject the second purge gas. The source gas, the first purge gas, the reactant gas, and the second purge gas may be injected in order, and the second gas injection unit 200 may inject the first purge gas as plasma and may inject one or more of the reactant gas and the second purge gas as plasma. The second gas injection unit 200 may inject a treatment gas, supplied from a treatment gas supply source 960 connected to one of the reactant gas injection hole 920 and the second purge gas injection hole 930, into the second region 20. The second gas injection unit 200 may inject the second purge gas, and then, may convert the treatment gas into plasma and may inject the treatment gas into the second region 20 in a plasma state.

The second gas injection unit 200 may include the plurality of reactant gas injection holes 920 which inject the reactant gas, the plurality of second purge gas injection holes 930 which inject the second purge gas, and the treatment gas supply source 960 connected to one of the reactant gas injection hole 920 and the second purge gas injection hole 930. The source gas, the first purge gas, the reactant gas, the second purge gas, and the treatment gas may be injected in order, and the second gas injection unit 200 may inject the treatment gas as plasma and may inject one or more of the first purge gas, the reactant gas, and the second purge gas as plasma.

The third gas injection unit 300 which injects the third purge gas into the third region 30 between the first region 10 and the second region 20 may include a third electrode unit 230. The third electrode unit 230 may include a first electrode 210b and a second electrode 220b . The first electrode 210b and the second electrode 220b may have an electric potential difference, and the third purge gas may pass through a region between the first electrode 210b and the second electrode 220b and thus may be injected into the third region 30 in a plasma state.

A fifth flow path 310 and a sixth flow path 320 may be installed in the third gas injection unit 300. The fifth flow path 310 and the sixth flow path 320 may be a flow path having a gun drill structure having a long-hole pipe shape. The fifth flow path 310 and the sixth flow path 320 may pass through the first electrode 210b , and thus, the third purge gas may be injected into the third region 30. The third gas injection unit 300 may include a third purge gas supply source (not shown) which injects the third purge gas. The third gas injection unit 300 may include a third electrode unit 230, and the third purge gas may pass through a region between the first electrode 210b and the second electrode 220b having an electric potential difference and may be injected into the third region 30 in a plasma state. The third purge gas may be injected into the third region 30 through one of the fifth flow path 310 and the sixth flow path 320, or the third purge gas may be injected through only one of the fifth flow path 310 and the sixth flow path 320. The third gas injection unit 300 may allow the third purge gas to pass through a region between the first electrode 210b and the second electrode 220b having an electric potential difference, and thus, may inject the third purge gas into the third region 30 in a plasma state. The third gas injection unit 300 may convert the third purge gas into plasma and may inject the third purge gas into the third region 30 in a plasma state. The first purge gas, the reactant gas, the second purge gas, or the third purge gas may be connected to a remote plasma generating device (not shown).

A first RF power source 702 and a ground may be connected to the second electrode unit 220 connected to the second gas injection unit 200 of the second region 20, and the first RF power source 702 or the ground may be selectively connected to the first electrode 210a or the second electrode 220a of the second electrode unit 220.

A third RF power source 706 and a ground may be connected to the third electrode unit 230 connected to the third gas injection unit 300 of the third region 30, and the third RF power source 706 or the ground may be selectively connected to the first electrode 210b or the second electrode 220b of the third electrode unit 230.

One or more protrusion electrodes (not shown) may be formed in the first electrode 210c of the first region 10, the first electrode 210a of the second region 20, and the first electrode 210b of the third region 30 in a direction toward the substrate supporting unit 600.

The second gas injection unit 200 may be connected to a remote plasma device (not shown) outside the chamber. Therefore, the second gas injection unit 200 may inject an ionized gas or a radical into the first region 10 and the second region 20.

Referring to FIG. 3, the third gas injection unit 300 injects the purge gas to the third region 30. The third gas injection unit 300 may divide the third region 30 into a first zone 302, a second zone 304, and a third zone 306 and may inject the purge gas into the third region 30.

The third purge gas may be injected into the first zone 302, the second zone 304, and the third zone 306, and the third purge gas may be injected as a plasmatic gas. The third zone 306 may be disposed at a center of a lid and may inject a center purge gas.

A first plasma injection unit 302a may be connected to the remote plasma device (not shown) so as to inject an ionized gas or a radical.

The source gas injected from the first gas injection unit 100 into the first region 10 may include a titanium family element (Ti, Zr, Hf, etc.), silicon (Si), or aluminum (Al). For example, a source gas SG including titanium (Ti) may be a titanium tetrachloride (TiC1₄) gas or the like. Also, the source gas SG containing silicon (Si) may be a silane (SiH₄) gas, a disilane (Si₂H₆) gas, a trisilane (Si₃H₈) gas, a tetraethylorthosilicate (TEOS) gas, a dichlorosilane (DCS) gas, a hexachlorosilane (HCD) gas, a tri-dimethylaminosilane (TriDMAS) gas, a trisilylamine (TSA) gas, or the like.

The reactant gas supplied from the second gas injection unit 200 to the second region 20 may include a hydrogen (H₂) gas, a nitrogen (N₂) gas, an oxygen (O₂) gas, a nitrous oxide (N₂O) gas, an ammonia (NH₃) gas, a vapor (H₂O) gas, or an ozone (O₃) gas. In this case, the reactant gas may be mixed with a purge gas including a nitrogen (N₂) gas, an argon (Ar) gas, a xenon (Ze) gas, or a helium (He) gas.

Moreover, a gas for generating plasma in the first region 10, the second region 20, and the third region 30 may include a hydrogen (H₂) gas, a nitrogen (N₂) gas, a mixed gas of a hydrogen (H₂) gas and a nitrogen (N₂) gas, an oxygen (O₂) gas, a nitrous oxide (N₂O) gas, an argon (Ar) gas, a helium (He) gas, or an ammonia (NH₃) gas.

The purge gas supplied to the first region 10, the second region 20, and the third region 30 may include a nitrogen (N₂) gas, an argon (Ar) gas, a xenon (Ze) gas, or a gelium (He) gas. The gases may be inert gases.

The first purge gas may inject the purge gas into the first region 10. The first purge gas injection hole 530 may be installed in the first gas injection unit 100. A plasmatic purge gas may be injected into the first region 10 through the first electrode unit 210. Therefore, the source gas may be adsorbed onto a substrate in the first region 10, and then, before the substrate supporting unit 600 rotates, the first purge gas injection hole 530 of the first electrode unit 210 may inject a plasmatic purge gas onto a substrate in the first region 10. That is, by using the plasmatic purge gas of the first purge gas injection hole 530, pre-treatment may be performed on the source gas adsorbed onto the substrate. Accordingly, the internal impurities of the source gas adsorbed onto the substrate may be removed, thereby contributing to enhancing the quality of a thin film deposited on the substrate.

A step of mounting each of the first substrate 601 and a second substrate 602 on the substrate supporting unit 600 disposed in the chamber may be performed so that the first substrate 601 is disposed in the first region 10 of the process space 1 of the chamber and the second substrate 602 is disposed in the second region 20 of the process space 1 spatially apart from the first region 10. Subsequently, a source adsorbing step of injecting the source gas from the first region 10 onto the first substrate 601 to adsorb the first source gas onto the first substrate 601 may be performed. A first rotation step of rotating the substrate supporting unit 600 may be performed so that the first substrate 601 with the first source gas adsorbed thereon is disposed in the second region 20. A thin film forming step of injecting the reactant gas onto the first substrate 601 and allowing the reactant gas to react with the first source gas adsorbed onto the first substrate 601 in the second region 20 to form a thin film and a second rotation step of rotating the substrate supporting unit 600 to place the first substrate 601, on which the thin film is formed, in the first region 10 may be performed. The source adsorbing step, the first rotation step, the thin film forming step, and the second rotation step may be repeatedly performed a plurality of times until a thin film having a predetermined thickness is formed.

After the source adsorbing step, a source purging step of injecting the first purge gas for purging the source gas which is on the first region 10 and the first substrate 601 and in an internal pattern of the first substrate 601 and is not adsorbed onto the first substrate 601 may be performed. After the thin film forming step, a reactant gas purging step of injecting the second purge gas for purging the reactant gas which is on the second region 20 and the first substrate 601 and in the internal pattern of the first substrate 601 may be performed. One or more of the reactant gas and the second purge gas may be converted into plasma and injected. The first purge gas may be converted into plasma and injected. After the thin film forming step, a reactant gas purging step of injecting the second purge gas, purging the reactant gas, onto the first substrate 601 may be performed, the first purge gas may be converted into plasma and injected, and one or more of the reactant gas and the second purge gas may be converted into plasma and injected. After the reactant gas purging step, a treatment gas injecting step of injecting the treatment gas for performing treatment on a thin film may be performed. Also, the treatment gas may be converted into plasma and injected.

A reactant gas purging step of injecting the second purge gas, purging the reactant gas, onto the first substrate 601 may be performed after the thin film forming step, a treatment gas injecting step of injecting the treatment gas for performing treatment on the thin film may be performed after the reactant gas purging step, the treatment gas may be converted into plasma and injected, and one or more of the first purge gas, the reactant gas, and the second purge gas may be converted into plasma and injected.

Plasma may be generated by injecting the first purge gas, the reactant gas, the second purge gas, the third purge gas, or the treatment gas into each region between the first electrodes 210c , 210a , and 230c and the second electrodes 220c , 220a , and 230b . The first rotation step or the second rotation step performed on the substrate supporting unit 600 may inject the third purge gas so as to divide the first region and the second region. In the first rotation step or the second rotation step, the third purge gas may be injected for additionally purging the first source gas adsorbed onto the first substrate 601 or additionally purging the reactant gas formed on the first substrate 601, and the third purge gas may be converted into plasma and injected.

An operation of injecting the reactant gas onto the second substrate 602 in the second region 20 in the source adsorbing step and an operation of injecting the source gas onto the second substrate 602 in the first region 10 in the thin film forming step may be further performed, and an operation of injecting the source gas onto the first substrate 601 in the first region 10 and an operation of injecting the reactant gas onto the second substrate 602 in the second region 20 may be simultaneously performed. An operation of injecting the reactant gas onto the second substrate 602 in the second region 20 in the source adsorbing step and an operation of injecting the source gas onto the second substrate 602 in the first region 10 in the thin film forming step may be further performed, and an operation of injecting the reactant gas onto the first substrate 601 in the second region 20 and an operation of injecting the source gas onto the second substrate 602 in the first region 10 and may be simultaneously performed.

The second purge gas of the second region 20 may be injected. The second electrode unit 220 may be installed, and thus, the second purge gas may be plasmatic and may be injected into the second region 20. Therefore, in the second region 20, the source gas adsorbed onto the substrate may react with the reactant gas and thus a thin film may be deposited through an atomic layer deposition (ALD) process, and then, the second purge gas may be plasmatic and post-treatment may be performed thereon. Therefore, the internal impurities of the thin film deposited on the substrate may be removed, and thus, the thin film deposited on the substrate may be densified. Accordingly, the quality of the thin film deposited on the substrate may be more enhanced.

The substrate processing apparatus according to the present inventive concept may stop the substrate in the first region 10 to adsorb the source gas thereon, rotate the substrate supporting unit 600 to rotate the substrate supporting unit 600 from the first region 10 to the second region 20, stop the substrate supporting unit 600 to deposit the reactant gas thereon in the second region 20, and rotate the substrate supporting unit 600 to repeatedly move the substrate to the first region 10 via the second region 20 again. Through such a process, the substrate processing apparatus according to the present inventive concept may perform a processing process on the substrate.

In this case, the substrate supporting unit 600 may be rotated by a rotation unit (not shown). A process of rotating the substrate supporting unit 600 by using the rotation unit will be described below.

First, when the first substrate 601 and the second substrate 602 are placed in the first region 10 and the second region 20, the rotation unit may stop the substrate supporting unit 600. Therefore, an adsorption process of adsorbing the source gas onto the substrate in the first region 10 in a state where the substrate stops may be performed. In this case, the first gas injection unit 100 may inject the source gas into the first region 10. In a state where the substrate supporting unit 600 stops, after the adsorption process stops, the first purge gas may be injected into the first region 10, and the first purge gas may be a plasmatic purge gas. Pre-treatment may be performed on the source gas adsorbed onto the first substrate 601 by using the plasmatic first purge gas, and subsequently or simultaneously, an undesired source gas remaining in the first region 10 may be purged or exhausted to the outside of the chamber by using the first purge gas.

When the purging or exhausting of the undesired source gas is completed, the rotation unit (not shown) may rotate the substrate supporting unit 600 so that the substrate moves from the first region 10 to the second region 20 via the third region 30 which is curtain purge. In this case, while the substrate is passing through the first zone 302 of the third region 30, the rotation unit may continuously rotate the substrate supporting unit 600 without stopping the substrate supporting unit 600. While the first substrate 601 is passing through the first zone 302, the first substrate 601 may be exposed to the purge gas or a plasmatic purge gas.

Subsequently, when the substrate is placed in the second region 20, the rotation unit may stop the substrate supporting unit 600. Therefore, in a state where the substrate stops, a process of depositing a thin film on the basis of a reaction between the source gas adsorbed onto the substrate and a reactant gas injected by the second gas injection unit 200 may be performed in the second region 20. The second gas injection unit 200 may activate the reactant gas by using plasma and may inject an activated reactant gas into the second region 20. In this case, the substrate processing apparatus according to the present inventive concept may be implemented to be suitable for a low temperature process. For example, the substrate processing apparatus according to the present inventive concept may be implemented to be suitable for a semiconductor high-K process. The second gas injection unit 200 may inject the reactant gas into the second region 20 in a state which does not activate the reactant gas. In this case, the substrate processing apparatus according to the present inventive concept may be implemented to be suitable for a high temperature process. For example, the substrate processing apparatus according to the present inventive concept may be implemented to be suitable for a semiconductor high temperature nitride process. When a deposition process is completed, the second purge gas may be injected into the region 20, and the second purge gas may be a plasmatic purge gas. A plasmatic gas may be injected onto a deposition thin film of the first substrate 601 by using the plasmatic second purge gas, and subsequently or simultaneously, an undesired reactant gas remaining in the second region 20 may be purged or exhausted to the outside of the chamber by using the first purge gas. Subsequently, post-treatment may be performed by injecting the treatment gas, which is for removing the impurities of a thin film, onto the thin film of the first substrate 601 once more.

When a deposition process and a treatment process are completed in a state where the substrate supporting unit 600 stops, the rotation unit may rotate the substrate supporting unit 600 so that the substrate moves from the second region 20 to the first region 10 via the second zone 304. In this case, while the substrate is passing through the second zone 304, the rotation unit may continuously rotate the substrate supporting unit 600 without stopping the substrate supporting unit 600. While the first substrate 601 is passing through the second zone 304, zones of the first region 10 and the second region 20 may be divided by using the purge gas injected by a second plasma injection unit 304b , and depending on the case, a plasmatic purge gas may be injected.

Furthermore, a processing process may be performed on the substrate without using plasma in all of the first region 10 and the second region 20. It is possible to implement a high temperature process by performing a thermal process in the second region 20. In this case, the high temperature process and injection of the reactant gas may be alternately performed in the second region 20. Therefore, step coverage of a high dielectric material or the like may be improved. Also, the present inventive concept may be implemented to alternately perform the high temperature process and the ALD process, and thus, a thickness of a thin film may more increase than a case where a thin film is deposited through only the ALD process.

Those skilled in the art can understand that the present inventive concept can be embodied in another detailed form without changing the technical spirit or the essential features. Therefore, it should be understood that the embodiments described above are exemplary from every aspect and are not restrictive. It should be construed that the scope of the present inventive concept is defined by the below-described claims instead of the detailed description, and the meanings and scope of the claims and all variations or modified forms inferred from their equivalent concepts are included in the scope of the present inventive concept.

1. An apparatus for processing a substrate, the apparatus comprising:
a chamber;
a substrate supporting unit where one or more substrates are mounted in a process space of the chamber, the substrate supporting unit being rotatably installed;
a first gas injection unit for injecting a source gas and a first purge gas into a first region of the process space, the first purge gas is for purging the source gas;
a source gas supply source for supplying the source gas to the first gas injection unit;
a first purge gas supply source for supplying the first purge gas to the first gas injection unit;
a second gas injection unit for injecting a reactant gas and a second purge gas into a second region of the process space spatially apart from the first region, the reactant gas is for reacting with the source gas and the second purge gas is for purging the reactant gas;
a reactant gas supply source for supplying the reactant gas to the second gas injection unit; and
a second purge gas supply source for supplying the second purge gas to the second gas injection unit.

2. The apparatus of claim 1, wherein the first gas injection unit comprises:
a plurality of source gas injection holes injecting the source gas; and
a plurality of first purge gas injection holes injecting the first purge gas.

3. The apparatus of claim 1, wherein the second gas injection unit comprises:
a plurality of reactant gas injection holes injecting the reactant gas; and
a plurality of second purge gas injection holes injecting the second purge gas.

4. The apparatus of claim 3, wherein the second gas injection unit injects one or more of the reactant gas and the second purge gas as plasma.

5. The apparatus of claim 4, wherein the second gas injection unit comprises a second electrode unit for converting the reactant gas or the second purge gas into plasma.

6. The apparatus of claim 2, wherein the first gas injection unit injects the first purge gas as plasma.

7. The apparatus of claim 6, wherein the first gas injection unit comprises a first electrode unit for converting the first purge gas into plasma.

8. The apparatus of claim 2, wherein
the second gas injection unit comprises a plurality of reactant gas injection holes injecting the reactant gas and a plurality of second purge gas injection holes injecting the second purge gas,
the second gas injection unit injects the source gas, the first purge gas, the reactant gas, and the second purge gas in order,
the second gas injection unit injects the first purge gas as plasma, and
the second gas injection unit injects one or more of the reactant gas and the second purge gas as plasma.

9. The apparatus of claim 3, wherein the second gas injection unit further comprises a treatment gas supply source connected to one of the reactant gas injection holes and the second purge gas injection holes.

10. The apparatus of claim 9, wherein the second gas injection unit injects the second purge gas, and then, injects a treatment gas as plasma.

11. The apparatus of claim 2, wherein
the second gas injection unit comprises a plurality of reactant gas injection holes injecting the reactant gas, a plurality of second purge gas injection holes injecting the second purge gas, and a treatment gas supply source connected to one of the reactant gas injection holes and the second purge gas injection holes,
the second gas injection unit injects the source gas, the first purge gas, the reactant gas, the second purge gas, and a treatment gas in order,
the second gas injection unit injects the treatment gas as plasma, and
the second gas injection unit injects one or more of the reactant gas and the second purge gas as plasma.

12. The apparatus of claim 5, wherein
each of a first electrode unit and the second electrode unit is configured with a first electrode and a second electrode having an electric potential difference therebetween, and
plasma is generated by injecting one of the first purge gas, the reactant gas, and the second purge gas into a region between the first electrode and the second electrode.

13. The apparatus of claim 3, further comprising:
a third gas injection unit injecting a third purge gas into a third region between the first region and the second region; and
a third purge gas supply source injecting the third purge gas into the third gas injection unit.

14. The apparatus of claim 13, wherein the third purge gas is injected in a plasma state.

15. The apparatus of claim 14, wherein the third purge gas unit comprises a third electrode unit for converting the third purge gas into plasma.

16. The apparatus of claim 15, wherein
the third electrode unit is configured with a first electrode and a second electrode having an electric potential difference therebetween, and
plasma is generated by injecting the third purge gas into a region between the first electrode and the second electrode.

17. The apparatus of claim 4, wherein one of the first purge gas, the reactant gas, and the second purge gas is connected to a remote plasma generating device.

18. (canceled)

19. (canceled)

20. (canceled)

21. (canceled)

22. (canceled)

23. (canceled)

24. (canceled)

25. (canceled)

26. (canceled)

27. (canceled)

28. (canceled)

29. (canceled)

30. (canceled)

31. (canceled)

32. (canceled)

33. (canceled)

34. (canceled)

35. The apparatus of claim 7, wherein
each of the first electrode unit and a second electrode unit is configured with a first electrode and a second electrode having an electric potential difference therebetween, and
plasma is generated by injecting one of the first purge gas, the reactant gas, and the second purge gas into a region between the first electrode and the second electrode.

36. The apparatus of claim 6, wherein one of the first purge gas, the reactant gas, and the second purge gas is connected to a remote plasma generating device.

37. The apparatus of claim 8, wherein one of the first purge gas, the reactant gas, and the second purge gas is connected to a remote plasma generating device.
